(19) United States
(12) Patent Application Publication
(10) Pub. No.: US 2008/0213496 A1
(43) Pub. Date: Sep. 4, 2008

(54) Method of coating semiconductor processing apparatus with protective yttrium-containing coatings

(75) Inventors: Jennifer Y. Sun, Sunnyvale, CA (US); Shun Jackson Wu, Cupertino, CA (US); Senh Thach, Union City, CA (US); Ananda Kumar, Fremont, CA (US); Robert W. Wu, Pleasanton, CA (US); Hong Wang, Cupertino, CA (US); Yixing Lin, Saratoga, CA (US); Clifford C. Stow, Boulder Creek, CA (US); Jim Dempster, Reno, CA (US); Li Xu, San Jose, CA (US); Kenneth S. Collins, San Jose, CA (US); Ren-Guan Duan, San Jose, CA (US); Thomas Graves, Los Altos, CA (US); Xiaoming He, Arcadia, CA (US); Jie Yuan, San Jose, CA (US)

Correspondence Address: SHIRLEY L. CHURCH, ESQ., P.O. BOX 81146, SAN DIEGO, CA, 92138, US

(73) Assignee: Applied Materials, Inc.

(21) Appl. No.: 11/890,221

(22) Filed: Aug. 2, 2007

Related U.S. Application Data
(63) Continuation-in-part of application No. 10/898,113, filed on Jul. 22, 2004.
Application No. 10/898,113 is a continuation-in-part of application No. 11/796,210, filed on Apr. 27, 2007.
Application No. 10/898,113 is a continuation-in-part of application No. 10/075,967, filed on Feb. 14, 2002, now Pat. No. 6,776,873.

(51) Int. Cl. C23C 4/10; C23C 14/34

(52) U.S. Cl. 427/453; 204/192.1

(57) ABSTRACT

Methods of applying specialty ceramic materials to semiconductor processing apparatus, where the specialty ceramic materials are resistant to halogen-comprising plasmas. The specialty ceramic materials contain at least one yttrium oxide-comprising solid solution. Some embodiments of the specialty ceramic materials have been modified to provide a resistivity which reduces the possibility of arcing within a semiconductor processing chamber.

The present application is a continuation-in-part application of application Ser. No. 10/898,113 of Jennifer Y. Sun et al., filed Jul. 22, 2004, titled: “Clean Dense Yttrium Oxide Coating Protecting Semiconductor Apparatus”, which is currently pending, and application Ser. No. 11/796,210, of Jennifer Y. Sun et al., filed Apr. 27, 2007, titled: “Method of Reducing The Erosion Rate Of Semiconductor Processing Apparatus Exposed To Halogen-Containing Plasmas”, which is currently pending. The present application is also related to a series of applications which have common inventorship with the present application. All of the additional, related applications listed below pertain to the use of a yttrium-oxide comprising ceramic to provide a plasma-resistant surface which is useful in semiconductor processing apparatus. The additional related applications include; U.S. application Ser. No. 11/796,211, of Sun et al., filed Apr. 27, 2007, titled: “Method And Apparatus Which Reduce The Erosion Rate Of Surfaces Exposed To Halogen-Containing Plasmas”, which is currently pending; U.S. application Ser. No. 10/918,232 of Sun et al., filed Aug. 13, 2004, titled: “Gas Distribution Plate Fabricated From A Solid Yttrium Oxide-Comprising Substrate”, which is currently pending; and U.S. application Ser. No. 10/075,967 of Sun et al., filed Feb. 14, 2002, titled: “Yttrium Oxide Based Surface Coating For Semiconductor IC Processing Vacuum Chambers”, which issued as U.S. Pat. No. 6,776,873 on Aug. 17, 2004. Additional related applications filed, which are a divisional and a continuation application of above-listed applications, include: U.S. application Ser. No. 11/595,484 of Wang et al., filed Nov. 10, 2006, titled: “Cleaning Method Used In Removing Contaminants From The Surface Of An Oxide or Fluoride Comprising a Group III Metal”, which is currently pending, and which is a divisional application of U.S. application Ser. No. 10/898,113; and U.S. application Ser. No. 11/592,905 of Wang et al., filed Nov. 3, 2006, titled: “Cleaning Method Used In Removing Contaminants From A Solid Yttrium Oxide-Containing Substrate”, which is currently pending, and which is a continuation application of U.S. application Ser. No. 10/918,232. The subject matter of all of these patents and applications is hereby incorporated by reference.

### BACKGROUND

1. Field

Embodiments of the present invention relate to a method of spray coating specialized yttrium oxide-comprising ceramic which is mainly comprised of solid solution ceramic which is highly resistant to plasmas of the kind which are present in semiconductor processing apparatus.

2. Background Art

This section describes background subject matter related to the disclosed embodiments of the present invention. There is no intention, either express or implied, that the background art discussed in this section legally constitutes prior art.

Corrosion (including erosion) resistance is a critical property for apparatus components and liners used in semiconductor processing chambers, where corrosive environments are present. Although corrosive plasmas are present in the majority of semiconductor processing environments, including plasma enhanced chemical vapor deposition (PECVD) and physical vapor deposition (PVD), the most corrosive plasma environments are those used for cleaning of processing apparatus and those used to etch semiconductor substrates. This is especially true where high-energy plasma is present and combined with chemical reactivity to act upon the surface of components present in the environment. The reduced chemical reactivity of an apparatus component surface or of a process chamber liner surface is an important property when corrosive gases, even in the absence of a plasma, are in contact with processing apparatus surfaces.

Process chamber liners and component apparatus present within the processing chambers used to fabricate electronic devices and micro-electro-mechanical systems (MEMS) are frequently constructed from aluminum and aluminum alloys. Surfaces of the process chamber and component apparatus (present within the chamber) are frequently anodized to provide a degree of protection from the corrosive environment. However, the integrity of the anodization layer may be deteriorated by impurities in the aluminum or aluminum alloy, so that corrosion begins to occur early, shortening the life span of the protective coating. The plasma resistance properties of aluminum oxide are not positive in comparison with some other ceramic materials. As a result, ceramic coatings of various compositions have been used in place of the aluminum oxide layer mentioned above; and, in some instances, have been used over the surface of the anodized layer to improve the protection of the underlying aluminum-based materials.

Yttrium oxide is a material which has shown considerable promise in the protection of aluminum and aluminum alloy surfaces which are exposed to halogen-containing plasmas of the kind used in the fabrication of semiconductor devices. An yttrium oxide coating has been used and applied over an anodized surface of a high purity aluminum alloy process chamber surface, or a process component surface, to produce excellent corrosion protection (e.g. U.S. Pat. No. 6,777,873 to Sun et al., mentioned above).

A film of Al₂O₃, or Al₂O₃ and Y₂O₃, has been formed on an inner wall surface of the chamber and on those exposed surfaces of the members within the chamber which require a high corrosion resistance and insulating property. In an exemplary application, a base material of the chamber may be a ceramic material (Al₂O₃, SiO₂, AlN, etc.), aluminum, or stainless steel, or other metal or metal alloy, which has a sprayed film over the base material. The film may be made of a compound of a III-B element of the periodic table, such as Y₂O₃ The film may substantially comprise a composite oxide consisting of Al₂O₃ and Y₂O₃. A sprayed film of yttrium-aluminum-garnet (YAG) may also be used. A typical thickness of a sprayed coating ranges from about 50 μm to 300 μm.

### SUMMARY

Specialty sintered ceramic materials have been developed which resist corrosion under semiconductor processing conditions which employ a halogen-containing plasma. The specialty materials have been modified to have improved plasma resistance and tailored mechanical properties in comparison with the sintered ceramic materials previously used for semiconductor processing apparatus. The electrical properties of the sintered ceramic materials have been adjusted so that the electrical resistivity properties of the materials (which have an effect in a plasma processing chamber) meet the requirements of critical chamber components. These electrical resistivity property requirements were previously met only by materials which exhibited low plasma resistance properties. The present specialty materials (which offer various combinations of plasma resistance, mechanical properties, and electrical resistivity properties) are sufficiently similar to those of semiconductor processing apparatus previously used. One advantage of the similar electrical properties is that it is not necessary to change the process recipes or general processing conditions which are currently in use in semiconductor device fabrication.

The sintered ceramic materials of interest comprise a yttrium oxide-based solid solutions. In one embodiment, the electrical resistivity of the sintered, yttrium oxide-comprising ceramic material is altered. In one exemplary embodiment technique, other oxides are added to the yttrium oxide, and the mixture is sintered. The positive ions of the other oxides have a different valence from the Y³⁺ ion, to form a Y vacancy, leading to a decrease of electrical resistivity. Examples of such other oxides include CeO₂, TiO₂, ZrO₂, HfO₂, and Nb₂O₅, by way of example and not by way of limitation. In an alternative exemplary embodiment technique, other oxides are added to the yttrium oxide and the mixture is sintered. The positive ions of the other oxide show the same valence as the Y³⁺ ion, but possess a significantly different ion radius than the Y³⁺ ion. The precursor mixture is sintered in a reductive atmosphere. This results in an O vacancy, which also decreases electrical resistivity. Examples of oxides which show the same valence as the Y³⁺ ion, but possess a significantly different ion radius include Nd₂O₃, Sm₂O₃, Sc₂O₃, Yb₂O₃, Er₂O₃, Ho₂O₃ and Dy₂O₃, by way of example and not by way of limitation.

One of the major components in a semiconductor processing chamber which requires a lower resistivity than is typical for yttrium-comprising sintered ceramics is the electrostatic chuck. The electrostatic chuck designers recommend that the resistivity of the dielectric surface of the electrostatic chuck fall within a range from about 10⁹ to 10¹¹ Ω·cm under semiconductor processing conditions, to reduce the possibility of plasma arcing at the electrostatic chuck. This resistivity range is equivalent to a conductivity within a range from about 10⁻⁹ to 10⁻⁷ S/m. This is a considerably lower resistivity than bulk Si₃N₄, for example, which exhibits a conductivity 10⁻¹³ S/m. For other corrosion resistant surfaces where plasma arcing might be a problem, such as lift pins, a resistivity in the range of that required for an electrostatic chuck is helpful. For corrosion resistant surfaces such as process chamber liners, the resistivity may be higher, possible as high as or exceeding about 10¹⁴ Ω·cm and still be acceptable.

At least one solid solution forms the major molar % of sintered ceramic materials which are useful as electrically modified corrosion-resistant materials. When there are two oxides used to form a solid solution, these oxides typically comprise yttrium oxide in combination with another oxide, which is typically selected from the group consisting of zirconium oxide, cerium oxide, hafnium oxide, niobium oxide, and combinations thereof. Use of other oxides such as scandium oxide, neodymium oxide, samarium oxide, ytterbium oxide, erbium oxide, and cerium oxide (and other lanthanide series element oxides) is considered to be acceptable in some instances.

When there are more than two oxides used to form the one or more solid solutions, these oxides typically comprise yttrium oxide, zirconium oxide, and at least one other oxide, which is typically selected from the group consisting of hafnium oxide, scandium oxide, neodymium oxide, niobium oxide, samarium oxide, ytterbium oxide, erbium oxide, cerium oxide, and combinations thereof. The use of other lanthanide series elements is also possible in particular instances. When the sintered ceramics comprise multi solid solution phases, typically there are two phases or three phases. In addition to the at least one solid solution-phase, there may be other phases within the sintered ceramic which are compounds or elemental metals.

By way of example, and not by way or limitation, with respect to sintered ceramics which make use of two precursor oxides, experiments have confirmed that a sintered ceramic comprising a solid solution, where yttrium oxide is present over a range from about 40 molar % to less than 100 molar %, and zirconium oxide is present over a range from more than 0 molar % to about 60 molar %, produces a sintered oxide having a resistivity which is in the range from about 10⁷ to about 10¹⁵ Ω·cm at room temperature. Resistivity over the same range is expected to be obtained from a combination of precursor oxides where yttrium oxide is present over a range from more than 0 molar % to less than 100 molar %, and cerium oxide is present over a range from greater than 0 molar % up to less than 10 molar %. Resistivity over a range from about 10⁹ to about 10¹¹ Ω·cm is also expected to be obtained from a combination of precursor oxides where yttrium oxide is present over a range from more than 0 molar % to less than 100 mole %, and hafnium oxide is present over a range from more than 0 molar % up to less than 100 molar %. Sintered ceramic exhibiting a resistivity over a range of about 10⁹ to about 10¹ Ω·cm is also expected to be obtained from a combination of precursor oxides where yttrium oxide is present over a range from about 48 molar % to less than 100 mole %, and niobium oxide is present over a range from greater than 0% up to about 52 molar %.

By way of example, and not by way of limitation, with respect to sintered ceramics which make use of more than two precursor oxides, in one embodiment, a sintered ceramic will exhibit a resistivity over a range of about 10⁷ to about 10¹⁵ Ω·cm when the sintered ceramic comprises a solid solution, and where the sintered ceramic material is formed from oxides where: yttrium oxide is present over a range from about 40 molar % to less than 100 molar %; zirconium oxide is present over a range from more than 0 molar % to about 50 molar %; and, scandium oxide is present over a range from more than about 0 molar % up to less than 100 molar %.

In another embodiment, a sintered ceramic will exhibit an electrical resistivity over a range of about 10⁷ to about 10¹⁵ Ω·cm when the sintered ceramic comprises a solid solution, and the sintered ceramic material is fabricated from oxides where: yttrium oxide is present over a range from about 40 molar % to less than 10 molar %; zirconium oxide is present over a range from more than 0 molar % to about 50 molar %, and hafnium oxide is present over a range from more than about 0 molar % up to less than 100 molar %.

In yet another embodiment, a sintered ceramic will exhibit a resistivity over a range of about 10⁷ to about 10¹⁵ Ω·cm when the sintered ceramic comprises a solid solution, and the sintered ceramic material is fabricated from oxides where: yttrium oxide is present over a range from about 40 molar % to less than 100 molar %; zirconium oxide is present over a range from more than 0 molar % to about 45 molar %; and, niobium oxide is present over a range from more than about 0 molar % up to about 80 molar %.

In one embodiment, the sintered ceramic material contains three phases, which include: a first phase solid solution comprising Y₂O₃—ZrO₂—Nb₂O₅ which makes up from about 60 molar % to about 90 molar % of the sintered ceramic material; a second phase of Y₃NbO₇ which makes up from about 5 molar % to about 30 molar % of the sintered ceramic material; and, a third phase of Nb in elemental form, which makes up from about 1 molar % to about 10 molar % of the sintered ceramic material.

In another embodiment of the sintered ceramic material which contains three phases, yttrium oxide is present over a range from about 60 molar % to about 75 molar %; zirconium oxide is present over a range from about 15 molar % to about 25 molar %, and niobium oxide is present over a range from about 5 molar % to about 15 molar %.

In sintered ceramic test specimens formed from a Y₂O₃—ZrO₂-MₓO_{y} material of the kind described above, in embodiments where M is scandium, hafnium, niobium, or neodymium, an erosion rate was demonstrated which was 0.16 μm/hour or less, after exposure for 76 hours to a CF₄/CHF₃ plasma. A similar erosion rate is expected when M is cerium, samarium, erbium, or another lanthanide series element. The plasma was formed in an Enabler for Trench Etch plasma processing chamber available from Applied Materials, Inc. The plasma source power was up to 2000 W, the process chamber pressure was 10-500 mTorr, and the substrate temperature was 40° C. This erosion rate of 0.16 μm/hour or less is equivalent to the erosion rate of pure Y₂O₃. Thus, the erosion rate of the sintered ceramics has been unaffected by the modification of the sintered ceramic to provide a lower resistivity sintered ceramic.

The sintered ceramic materials described above may be applied over a surface of an underlying structure. A mixture of the oxides used to form the sintered ceramic material will react with each other to form the solid solution and any compounds described above during the spraying process. The final phase composition of the sintered ceramic produced by the spraying process is the same as that of a ceramic produced by the bulk sintering process.

Although the semiconductor processing apparatus may be formed from a number of different substrates, aluminum has been preferred in the semiconductor industry due to the long history of performance characteristics observed for this material. It is possible to use an aluminum alloy of the 2000 series or the 5000 through 7000 Series as a substrate in fabricating process chambers and processing components, where the aluminum alloy is protected by a plasma-resistant coatings of the kind described above. The coated aluminum alloy has excellent plasma corrosion-resistance over a lifetime which is extended at least two times, and as much as four times, over the lifetime of an aluminum alloy which is not protected by a coating of the present invention.

To provide the extended lifetime corrosion resistance described, it is helpful to place the coating in compression. This is accomplished by controlling deposition conditions during application of the coating. Placing the coating under adequate compression helps prevent mobile impurities in the aluminum alloy substrate from migrating from the substrate into the coating and causing defects in the coating which enable penetration of the coating by reactive species which are in contact with the exterior surface of the coating. Placing the coating under compression also increases the density of the coating. The increased density of the coating provides better protection from corrosive plasmas and improves the machinability of a substrate protected by the sprayed film. Porosity is an indicator of the density of the coating, i.e., the less porous the coating, the more dense the coating. Porosity is expressed as the percentage of open space in the total volume of the coating. Yttrium oxide coatings which have been applied according to the present method have a porosity of about 1.4%. In comparison, yttrium oxide coatings which were deposited using prior art methods typically have porosities within the range of about 3% to about 5%.

To place the applied coating/film in compression, it is necessary to heat, at least to a nominal depth, the upper surface of the aluminum alloy substrate during application of the coating/film, so that upon cooling of the interfacial surface between the substrate and the coating, the coating is placed in compression by the contracting aluminum alloy. The upper surface of the aluminum alloy should be preheated to a depth of at least 250 mils (0.25 inch), and to a temperature of at least about 150-200° C. The upper end of the temperature to which the substrate may be preheated depends on the composition of the substrate, and the substrate should be heated to a temperature lower than the glass transition temperature of the substrate.

The film/coating may be applied using other methods in addition to thermal/flame spray, plasma discharge spray. For example, physical vapor deposition (PVD) in the form of sputtering of a target of the sintered bulk ceramic, and chemical vapor deposition (CVD) may also be used. The structure of the coating obtained may be somewhat different in each instance; however, one skilled in the art can readily make adjustments to bring the coating within the desired performance characteristics. When the coating is applied using sputtering or CVD, the application rate is much slower, and it may be advantageous to use the coating in combination with an underlying layer of aluminum oxide. Plasma spray coating and thermal spray coating have each provided excellent results, both directly over an aluminum alloy and over an aluminum oxide layer which overlies the aluminum alloy.

As discussed above, a plasma or thermal/flame sprayed coating may be applied over a bare aluminum alloy surface. Typically, the aluminum alloy has a very thin film of native aluminum oxide on its surface, due to exposure of the aluminum surface to air. It is advantageous to apply the thermal/flame sprayed or plasma sprayed coating over the bare aluminum alloy surface, or the surface exhibiting only a native oxide, as a better bond between the protective coating is achieved.

When the coated component is to be used in a plasma processing chamber where it will be exposed to chlorine species, the plasma sprayed or thermal/flame sprayed coating should be applied over an aluminum oxide film which is intentionally created upon the aluminum alloy surface, in order to better protect the underlying aluminum alloy from the corrosive chlorine plasma. In this instance, the thickness of the aluminum oxide film is within the range of about 0.5 mil to about 4 mils, and the temperature of the aluminum oxide film should be at least about 150-200° C. at the time of application of the protective yttrium oxide-comprising coating. The temperature of the aluminum oxide film at the time of application of the protective coating must not exceed the glass transition temperature of the aluminum oxide.

Typically, the aluminum alloy surface is pre-roughened prior to anodization and coating of the surface. The aluminum alloy surface can be pre-roughened using a technique such as bead blasting or, more typically by electrochemical etching, for example, and not by way of limitation.

The applied thickness of the protective yttrium oxide-comprising coating which provides improved mechanical strength, and which may provide reduced electrical resistivity, depends on the environment to which the aluminum alloy component or structure will be exposed during use. When the temperature to which the component or structure is exposed is lower, the thickness of the plasma sprayed or thermal/flame sprayed coating can be increased without causing a coefficient of expansion problem. For example, when the component or structure will be exposed to thermal cycling between about 15° C. and about 120° C., and the protective coating is thermal/flame sprayed or plasma sprayed over an aluminum alloy from the 2000 series or 5000 to 7000 series (having a native oxide present on its surface), the thickness of the yttrium oxide-comprising coating of the Type A ceramic material or Type B ceramic material should range between about 12 mils and about 20 mils. A coating having a thickness of about mils provides excellent results. A thinner coating down to about 10 mils thickness may be used in combination with an underlying aluminum oxide coating.

While the plasma-resistant coating applied by plasma spraying or thermal/flame spraying has produced excellent results, to further improve the performance of the plasma-resistant coating, it is advantageous to clean the coating after application to the substrate. The cleaning process removes trace metal impurities which may cause problems during semiconductor processing, and also removes loose particles from the surface of the coating which are likely to become contaminating particulates during the processing of product adjacent to the coated surface, especially when that product is a semiconductor device.

The cleaning process should remove undesired contaminants and deposition process by-products without affecting the performance capability of the protective coating, and without harming the underlying aluminum alloy surface. To protect the aluminum alloy surface while the coating is cleaned, the coating is first saturated with an inert solvent which would not harm the aluminum alloy upon contact. Typically, the coated substrate is immersed in a deionized water ultrasonic bath at a frequency of about 40 kHz (for example, and not by way of limitation) for a period of about 5 minutes to about 30 minutes. Subsequently, a chemically active solvent is applied to remove contaminants from the protective coating. Typically, the surface of the coated substrate is wiped with a soft wipe which has been wetted with a dilute acid solution for a period of about 3 minutes to about 15 minutes. The dilute acid solution typically comprises about 0.1 to about 5 volume % HF (more typically, about 1 to about 5 volume %); about 1 to about 15 volume % HNO₃ (more typically, about 5 to about 15 volume %); and about 80 to about 99 volume % deionized water. After wiping, the component is then rinsed with deionized water, followed by immersion in a deionized water ultrasonic bath at a frequency of about 40 kHz (for example, and not by way of limitation) for a period of about 30 minutes to about 2 hours (typically, for a period of about 40 minutes to about 1 hour).

In addition to removing impurities and contaminants from the coating surface, the step of wiping the coated component with the dilute HF solution provides fluorination to the coating surface. Fluorination of the coating surface results in a robust, stable coating which is inert to reactive plasmas. Fluorination of the coating surface can also be obtained by exposing the coated surface to a plasma containing fluorine species.

As previously discussed, the specialized ceramic materials described in detail herein may be created during were sintered during flame/thermal spraying or plasma spraying upon the surface of a substrate. In addition other application techniques which are known in the art, such as sputtering from a target of the sintered material or by chemical vapor deposition onto a substrate surface may be used to form a ceramic coating over the surface of a variety of substrates. Such substrates include metal and ceramic substrates, such as, but not limited to, aluminum, aluminum alloy, stainless steel, alumina, aluminum nitride and quartz.

### BRIEF DESCRIPTION OF THE DRAWINGS

To assist in the understanding of the above recited embodiments, a more particular description of specific embodiments described above may be had by reference to the appended drawings. It is to be noted, however, that the appended drawings illustrate only a portion of the typical embodiments, and are not therefore considered to be limiting in scope of the invention which is described herein. The invention includes other equally effective embodiments.

FIG. 1 is a graph 100 illustrating the electrical resistivity, as a function of temperature, for a variety of materials, where the applied voltage was 1000 V in an air environment.

FIG. 2 is a phase diagram 200 of Y₂O₃—ZrO₂—Al₂O₃. This phase diagram shows, among other compositions, the composition of a specialized material, identified herein as an area “A” on the phase diagram, for reference purposes. The type “A” ceramic material is a ceramic composition which has demonstrated excellent resistance to erosion by halogen plasmas.

FIG. 3 is a phase diagram 300 of Y₂O₃—ZrO₂—Nb₂O₅. This phase diagram shows, among other compositions, the composition of a specialized material, identified herein as an area “B” on the phase diagram, for reference purposes. The type “B” ceramic material is a ceramic composition which not only resists erosion by halogen plasmas, but which also exhibits a controlled, lower electrical resistivity than the type “A” ceramic material, for example.

FIG. 4 is a graph 400 illustrating electrical resistivity, as a function of applied voltage, for a variety of materials, where the measurement was made at room temperature (about 27° C.) in an air environment.

FIG. 5 is a bar chart 500 which shows the average exemplary erosion rate, normalized relative to that for pure yttrium oxide, for a variety of sintered ceramic materials which were exposed to a plasma generated from CF₄ and CHF₃ source gases.

FIG. 6 is a cross-sectional schematic 600 of a type of plasma spraying system which is useful in applying the specialized yttrium oxide-comprising coatings of the kind described herein.

### DETAILED DESCRIPTION OF EXEMPLARY EMBODIMENTS

As a preface to the detailed description, it should be noted that, as used in this specification and the appended claims, the singular forms “a”, and “the” include plural referents, unless the context clearly dictates otherwise.

When the word “about” is used herein, this is intended to mean that the nominal value presented is precise within ±10%.

Described herein are specialized ceramic materials which are developed to resist corrosion under semiconductor device processing conditions which employ a halogen-containing plasma. In certain embodiments, the specialty materials have been modified to have a reduced electrical resistivity when compared with similar ceramic materials which were developed previously to provide plasma erosion resistance. The reduced electrical resistivity is helpful in reducing the possibility of plasma arcing at various components within a semiconductor processing chamber, most notably upon a surface of an electrostatic chuck or a substrate lift pin, where plasma arcing is more of a problem, for example and not by way of limitation. In the past the component, or at least the surface of the component was fabricated from aluminum nitride or aluminum oxide, which might be doped to provide electrical properties. While this material provided the desired electrical properties, the corrosion/erosion rate was relatively rapid, limiting the useful lifetime of the particular component, and requiring more down time for repairs and replacement of component parts.

Further, the electrical properties of the various materials used as process chamber liners and functional components within a plasma processing semiconductor apparatus affect the behavior of the plasma. Changes in the behavior of the plasma affect the plasma processing characteristics, and when the effect is substantial, it is necessary to change other process variables to accommodate the change in the plasma behavior. Rather than rework processing variables for device fabrication, it is more practical to develop erosion resistant ceramic materials which have acceptable electrical properties. Only a portion of the ceramic materials which exhibit acceptable plasma corrosion/erosion characteristics can be modified to control electrical resistivity properties within the desired range useful for a component in contact with plasmas. One skilled in the art and having read the present description will be able to be relatively certain of success when selecting combinations of oxides to form the ceramic materials.

For reasons of convenience, the development of acceptable halogen plasma corrosion/erosion-resistant ceramic materials having the desired electrical properties was carried out by making use of sintered ceramics. The sintered ceramics were produced by techniques well known in the art. In other embodiments, acceptable halogen plasma corrosion/erosion-resistant ceramic materials of the same general composition may be applied as a coating over an underlying material, such as aluminum or aluminum alloy, for example, using thermal/flame spraying or plasma spraying. In the alternative, a sintered ceramic material may be used to fabricate a target which may be used to apply the ceramic material by physical vapor deposition over the underlying material, particularly when the apparatus over which the protective ceramic material is to be applied is large, such as a process chamber liner.

As previously discussed, the sintered ceramic materials of interest comprise yttrium oxide. The resistivity of the sintered, yttrium-comprising ceramic material may be altered. In one exemplary technique, at least one other oxide is added to the yttrium oxide and the mixture is sintered. The positive ions of the at least one other oxide have a different valence from the Y³⁺ ion, to form a Y vacancy, leading to a decrease of electrical resistivity. Examples of such oxides include CeO₂, TiO₂, ZrO₂, HfO₂, and Nb₂O₅, by way of example and not by way of limitation. In another exemplary technique, the at least one other oxide is added to yttrium oxide, and the mixture is sintered in a reductive atmosphere; however, the positive ions of the at least one other oxide show the same valence as the Y³⁺ ion, but possess a significantly different ion radius than the Y³⁺ ion. This results in an O vacancy, which also decreases electrical resistivity. Examples of oxides which show the same valence as the Y³⁺ ion, but possess a significantly different ion radius include Nd₂O₃, Sm₂O₃, Sc₂O₃, Yb₂O₃, Er₂O₃, Ho₂O₃ and Dy₂O₃, by way of example and not by way of limitation.

Although the semiconductor processing apparatus may be formed from a number of different substrates, aluminum has been preferred in the semiconductor industry due to the long history of performance characteristics observed for this material. It is possible to use an aluminum alloy of the 2000 series or the 5000 through 7000 Series as a substrate in fabricating process chambers and processing components, where the aluminum alloy is protected by a plasma-resistant coatings of the kind described above as an Type A ceramic or material or Type B ceramic material, which employ crystalline solid solutions of yttrium oxide. The coated aluminum alloy has excellent plasma corrosion-resistance over a lifetime which is extended at least two times, and as much as four times, over the lifetime of an aluminum alloy which is not protected by a coating of the present invention.

To provide the extended lifetime corrosion resistance described, it is helpful to place the coating in compression. Placing the coating under adequate compression helps prevent mobile impurities in the aluminum alloy substrate from migrating from the substrate into the coating and causing defects in the coating. Placing the coating under compression also increases the density of the coating. Porosity is an indicator of the density of the coating, i.e., the less porous the coating, the more dense the coating. Porosity is expressed as the percentage of open space in the total volume of the coating. Yttrium oxide coatings which have been applied according to the present method have a porosity of about 1.4%. In comparison, yttrium oxide coatings which were deposited using prior art methods typically have porosities within the range of about 3% to about 5%. To place the applied coating/film in compression, it is necessary to heat, at least to a nominal depth, the upper surface of the aluminum alloy substrate during application of the coating/film, so that upon cooling of the interfacial surface between the substrate and the coating, the coating is placed in compression by the contracting aluminum alloy. The upper surface of the aluminum alloy should be preheated to a depth of at least 250 mils (0.25 inch), and to a temperature of at least about 150-200° C. The upper end of the temperature to which the substrate may be preheated depends on the composition of the substrate, and the substrate should be heated to a temperature lower than the glass transition temperature of the substrate.

When the coated component is to be used in a plasma processing chamber where it will be exposed to chlorine species, the plasma sprayed or thermal/flame sprayed coating should be applied over an aluminum oxide film which is intentionally created upon the aluminum alloy surface, in order to better protect the underlying aluminum alloy from the corrosive chlorine plasma. In this instance, the thickness of the aluminum oxide film is within the range of about 0.5 mil to about 4 mils, and the temperature of the aluminum oxide film should be at least about 150-200° C. at the time of application of the protective yttrium oxide-comprising coating. The temperature of the aluminum oxide film at the time of application of the protective coating must not exceed the glass transition temperature of the aluminum oxide.

Typically, the aluminum alloy surface is pre-roughened prior to anodization and coating of the surface. The aluminum alloy surface can be pre-roughened using a technique such as bead blasting or, more typically by electrochemical etching, for example, and not by way of limitation.

The applied thickness of the protective yttrium oxide-comprising coating which employs crystalline solid solutions depends on the environment to which the aluminum alloy component or structure will be exposed during use. When the temperature to which the component or structure is exposed is lower, the thickness of the plasma sprayed or thermal/flame sprayed coating can be increased without causing a coefficient of expansion problem. For example, when the component or structure will be exposed to thermal cycling between about 15° C. and about 120° C., and the protective coating is thermal/flame sprayed or plasma sprayed over an aluminum alloy from the 2000 series or 5000 to 7000 series (having a native oxide present on its surface), the thickness of the yttrium oxide-comprising coating should range between about 12 mils and about 20 mils. A coating having a thickness of about 15 mils provides excellent results. A thinner coating down to about 10 mils thickness may be used in combination with an underlying aluminum oxide coating.

When thermal/flame spraying or plasma spraying is used, to further improve the performance of the protective, plasma-resistant coating, it is advantageous to clean the coating after application to the substrate. The cleaning process removes trace metal impurities which may cause problems during semiconductor processing, and also removes loose particles from the surface of the coating which are likely to become contaminating particulates during the processing of product adjacent to the coated surface, especially when that product is a semiconductor device.

The cleaning process should remove undesired contaminants and deposition process by-products without affecting the performance capability of the protective coating, and without harming the underlying aluminum alloy surface. To protect the aluminum alloy surface while the coating is cleaned, the coating is first saturated with an inert solvent which would not harm the aluminum alloy upon contact. Typically, the coated substrate is immersed in a deionized water ultrasonic bath at a frequency of about 40 kHz (for example, and not by way of limitation) for a period of about 5 minutes to about 30 minutes. Subsequently, a chemically active solvent is applied to remove contaminants from the protective coating. Typically, the surface of the coated substrate is wiped with a soft wipe which has been wetted with a dilute acid solution for a period of about 3 minutes to about 15 minutes. The dilute acid solution typically comprises about 0.1 to about 5 volume % HF (more typically, about 1 to about 5 volume %); about 1 to about 15 volume % HNO₃ (more typically, about 5 to about 15 volume %); and about 80 to about 99 volume % deionized water. After wiping, the component is then rinsed with deionized water, followed by immersion in a deionized water ultrasonic bath at a frequency of about 40 kHz (for example, and not by way of limitation) for a period of about 30 minutes to about 2 hours (typically, for a period of about 40 minutes to about 1 hour).

In addition to removing impurities and contaminants from the coating surface, the step of wiping the coated component with the dilute HF solution provides fluorination to the coating surface. Fluorination of the coating surface results in a robust, stable coating which is inert to reactive plasmas. Fluorination of the coating surface can also be obtained by exposing the coated surface to a plasma containing fluorine species, such as a CF₄ plasma or a CHF₃/CF₄ plasma having a density in the range of about 1×10⁹ e⁻/cm³, under conditions and for a period of time sufficient to provide a coating surface which is at least partially fluorinated.

The specialized ceramic materials described in detail herein were sintered during flame/thermal spraying or plasma spraying upon the surface of a substrate. However, as mentioned above other methods of applying coatings using the specialized ceramic materials is contemplated. For example, a coating may be sputtered from a target of sintered ceramic material, using techniques well known in the art. In addition, coatings having the specialized compositions described herein may be applied using chemical vapor deposition (CVD). The coatings may be applied over a variety of substrates, including, but not limited to, aluminum, aluminum alloy, stainless steel, alumina, aluminum nitride and quartz. These coating techniques are by way of example and not by way of limitation.

Typically, the spray coated ceramic material which improves mechanical properties is mainly comprised of at least one solid solution phase, and more typically two solid solution phases, which may exist in combination with compound and/or elemental phases. For example, the multi-phase ceramics typically contain one or two solid solution phases formed from yttrium oxide, zirconium oxide and/or rare earth oxides, in combination with an yttrium-aluminum compound. Ceramic materials formed from starting compositions in which the Y₂O₃, yttrium oxide, molar concentration ranges from about 50 mole % to about 75 mole %; the ZrO₂, zirconium oxide, molar concentration ranges from about 10 mole % to about 30 mole %; and the Al₂O₃, aluminum oxide, molar concentration ranges from about 10 mole % to about 30 mole % provide excellent erosion resistance to halogen-containing plasmas while providing advanced mechanical properties which enable handling of solid ceramic processing components with less concern about damage to a component. Other oxides which may be substituted for the aluminum oxide, to assist in improvement of mechanical properties include HfO₂, hafnium oxide; Sc₂O₃, scandium oxide; Nd₂O₃, neodymium oxide; Nb₂O₅, niobium oxide; Sm₂O₃, samarium oxide; Yb₂O₃, ytterbium oxide; Er₂O₃, erbium oxide; Ce₂O₃ (or CeO₂), cerium oxide, or combinations thereof.

As a matter of general reference, a composite material is made up from two or more constituent materials with significantly different physical or chemical properties which remain separate and distinct on a macroscopic level within the finished structure. The constituent materials consist of a matrix and reinforcement. The matrix material surrounds and supports at least one reinforcement material by maintaining a relative position with respect to the reinforcement material. However, the constituent materials have significantly different properties, which remain separate and distinct on a macroscopic level within the finished structure. This kind of material is distinct from the kinds of ceramic materials which are formed by thermal/flame spraying or plasma spraying as described herein.

In addition to the spray coated specialized yttrium oxide-comprising materials which exhibit improved mechanical strength, similar ceramic materials which offer a reduced electrical resistivity may be spray coated as well. The reduced electrical resistivity is helpful in reducing the possibility of plasma arcing at various components within a semiconductor processing chamber, most notably upon a surface of an electrostatic chuck or a substrate lift pin, for example and not by way of limitation. In the past a component, or at least the surface of the component, which was fabricated from aluminum nitride, which might be doped to provide electrical properties. While this material provided the desired electrical properties, the corrosion/erosion rate of the aluminum nitride was relatively rapid, limiting the useful lifetime of the particular component, and requiring more down time for repairs and replacement of component parts.

As previously discussed, the sintered ceramic materials of interest comprise yttrium oxide. The resistivity of the sintered, yttrium-comprising ceramic material may be altered. In one exemplary technique, at least one other oxide is added to the yttrium oxide and the mixture is sintered. The positive ions of the at least one other oxide have a different valence from the Y³⁺ ion, to form a Y vacancy, leading to a decrease of electrical resistivity. Examples of such oxides include CeO₂, TiO₂, ZrO₂, HfO₂, and Nb₂O₅, by way of example and not by way of limitation. In another exemplary technique, the at least one other oxide is added to yttrium oxide, and the mixture is sintered in a reductive atmosphere; however, the positive ions of the at least one other oxide show the same valence as the Y³⁺ ion, but possess a significantly different ion radius than the Y³⁺ ion. This results in an O vacancy, which also decreases electrical resistivity. Examples of oxides which show the same valence as the Y³⁺ ion, but possess a significantly different ion radius include Nd₂O₃, Sm₂O₃, Sc₂O₃, Yb₂O₃, Er₂O₃, Ho₂O₃ and Dy₂O₃, by way of example and not by way of limitation.

A number of exemplary sintered ceramic materials have been investigated to date, and the TABLE below provides an illustration of a portion of the sintered ceramic materials which were created and evaluated. The evaluation of these materials is discussed subsequently.

### EXAMPLES

TABLE

| | | | Precursor | | | | |
|---|---|---|---|---|---|---|---|
| | | | Weight | Melting | Sintering | | |
| Sample | Precursor | Precursor | Parts/100 | Point | Temp. | Phase | Density |
| # | Molar % | Weight % | Y₂O₃ | (° C.) | (° C.) | Comp. | (g/cm³) |
| 1 | Y₂O₃: 75.0 | Y₂O₃: 77.82 | Y₂O₃: 100.00 | 2800 | >1800 | c-ss | 5.607 |
| | HfO₂: 20.0 | HfO₂: 19.35 | HfO₂: 24.86 | | | single | |
| | ZrO₂: 5.0 | ZrO₂: 2.83 | ZrO₂: 3.64 | | | phase** | |
| 2 | Y₂O₃: 60.0 | Y₂O₃: 72.18 | Y₂O₃: 100.00 | 2360 | >1800 | c-ss | 4.936 |
| | Sc₂O₃: 20.0 | Sc₂O₃: 14.69 | Sc₂O₃: 20.36 | | | single | |
| | ZrO₂: 20.0 | ZrO₂: 13.13 | ZrO₂: 18.19 | | | phase** | |
| 3 | Y₂O₃: 60.0 | Y₂O₃: 59.58 | Y₂O₃: 100.00 | N/A* | >1800 | c-ss | 5.555 |
| | Nd₂O₃: 20.0 | Nd₂O₃: 29.58 | Nd₂O₃: 49.66 | | | single | |
| | ZrO₂: 20.0 | ZrO₂: 10.84 | ZrO₂: 18.19 | | | phase** | |
| 4 | Y₂O₃: 70.0 | Y₂O₃: 75.53 | Y₂O₃: 100.00 | N/A* | >1800 | c-ss** | 5.331 |
| | Nb₂O₅: 10.0 | Nb₂O₅: 12.7 | Nb₂O₅: 16.82 | | | Y₃NbO | |
| | ZrO₂: 20.0 | ZrO₂: 11.77 | ZrO₂: 15.59 | | | and Nb | |

*N/A = not available
**c-ss is cubic yttria-type solid solution.

### Example One

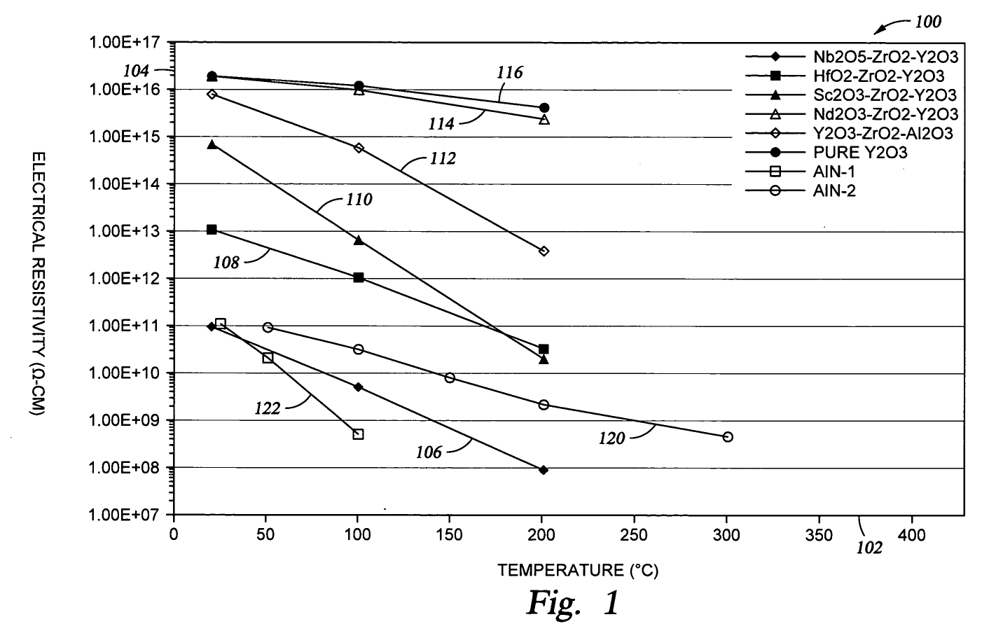

FIG. 1 shows a graph 100 illustrating electrical resistivity of a variety of ceramic materials, including the Type A and Type B materials made according to exemplary embodiments of the invention. The resistivity is shown on axis 104, as a function of temperature, which is shown on axis 102. The resistivity was measured at 1000 V in an air environment, using standard test conditions in accordance with ASTM D 1829-66 or JIS C2141.

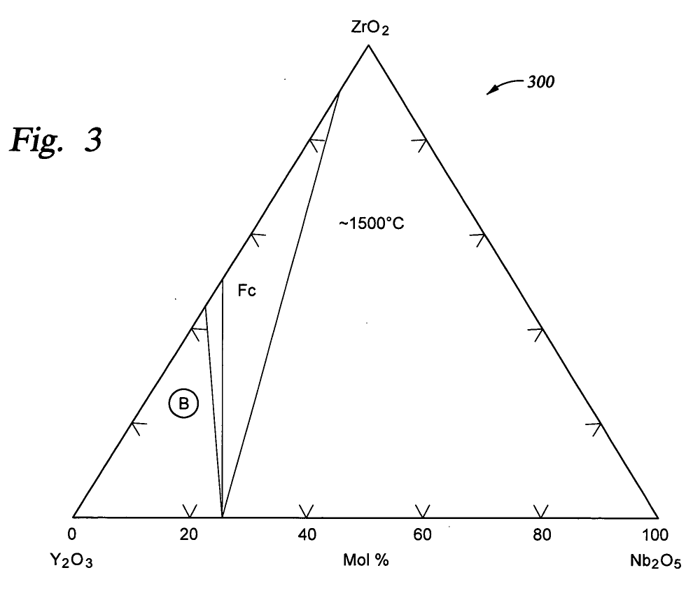

Curve 106 shown in FIG. 1 is representative of the Nb₂O₅-comprising sintered ceramic material which is described as Sample #4 in the Table. With respect to sintered ceramic material comprising Nb₂O₅, acceptable electrical resistivity values are expected to be obtained for additional compositions as well, as illustrated by the phase diagram shown in FIG. 3. The sintered ceramic material contains three phases, which include a first phase solid solution comprising Y₂O₃—ZrO₂—Nb₂O₅ which may make up about 60 molar % to about 90 molar % of the sintered ceramic material; a second phase of Y₃NbO₇ which may make up from about 5 molar % to about 30 molar % of the sintered ceramic material; and, a third phase of Nb in elemental form, which may make up from about 1 molar % to about 10 molar % of the sintered ceramic material. This material is particularly useful when the resistivity needs to be low to prevent arcing. The resistivity is lower than about 10¹¹ Ω·cm at room temperature and about 10⁸ Ωcm at 200° C., and may exhibit a resistivity in the range of 10⁹ Ω·cm at typical semiconductor processing conditions.

One embodiment of the Nb₂O₅-comprising sintered ceramic material illustrated in FIG. 1 is referred to as Nb₂O₅—ZrO₂—Y₂O₃. With reference to FIG. 3, one area of the phase diagram has been labeled as “B”. This designation indicates that the solid solution composition of a sintered ceramic material comprises Y₂O₃ at a concentration ranging from about 55 molar % to about 80 molar %, ZrO₂ at a concentration ranging from about 5 molar % to about 25 molar %, and an additive such as Nb₂O₅, HfO₂, Nd₂O₃, or Sc₂O₃ at a concentration ranging from about 5 molar % to about 25 molar %.

### Example Two

Curve 108 shown in FIG. 1 is representative of the HfO₂-comprising sintered ceramic material, made in accordance with the present invention, which is also described as Sample #1 in the Table. This ceramic material exhibits a higher resistivity than the Nb₂O₅-comprising material, but is useful for fabricating semiconductor processing apparatus components where arcing is less critical than with respect to an electrostatic chuck or a substrate lift pin.

### Example Three

Curve 110 shown in FIG. 1 is representative of the Sc₂O₃-comprising sintered ceramic material, made in accordance with the present invention, which is also described as Sample 2 in the Table. Again, this material may be used in applications where the resistivity requirement is 10¹¹ Ω·cm.

### Example Four

### Comparative Example

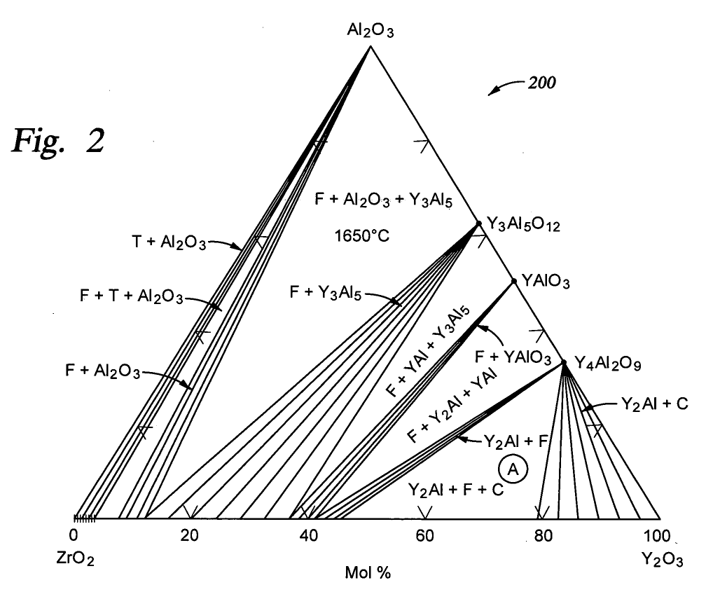

Curve 112 shown in FIG. 1 is representative of the Y₂O₃—ZrO₂—Al₂O₃ material which is illustrated in the FIG. 2 phase diagram. This material is described for purposes of a comparative example only with respect to the controlled resistivity ceramic materials. This sintered ceramic material comprises a solid solution which is formed from Y₂O₃ and ZrO₂, and a compound which is formed from Y₂O₃ and Al₂O₃ oxides. A typical sintered ceramic material is formed from Y₂O₃ at a concentration ranging from about 60 molar % to about 65 molar %; ZrO₂ at a concentration ranging from about 20 molar % to about 25 molar %; and, Al₂O₃ at a concentration ranging from about 10 molar % to about 15 molar %. One embodiment of a centered ceramic material, which is illustrated by area “A” in the phase diagram in FIG. 2, and which is represented by the graph for Y₂O₃—ZrO₂—Al₂O₃ shown in FIG. 1, contains: about 60 molar % solid solution with a cubic yttria type crystal structure, where c-Y₂O₃ is a solvent, with Zr₂O₃ solute; about 2 molar % solid solution with a fluorite type crystal structure, where ZrO₂ is a solvent, with Y₂O₃ solute; and about 38 molar % YAM (Y₄Al₂O₉) compound.

### Example Five

### Comparative Example

Curve 114 of FIG. 1 is representative of the Nd₂O₃-comprising sintered ceramic material which is described as Sample #3 in the Table. This material is failed to meet the requirements which are necessary to prevent arcing, and is considered to be a comparative example which is not part of the unique ceramic materials which make up the invention.

### Example Six

### Comparative Example

Curve 116 of FIG. 1 is representative of the electrical resistivity characteristics observed for a sintered ceramic of pure Y₂O₃. This material is also a comparative example, which is useful as a baseline, since a number of semiconductor apparatus components have been fabricated from pure Y₂O₃. A comparison of the resistivity of the pure Y₂O₃ shows the very significant improvement in terms of electrical resistivity which is achieved by the present invention.

Also shown in FIG. 1 are curves 120, which represents a doped aluminum nitride of the kind commonly used to fabricate an electrostatic chuck, and 122 which represents a second doped aluminum nitride which is also used to fabricate an electrostatic chuck and other semiconductor processing apparatus which requires a low electrical resistivity.

### Example Seven

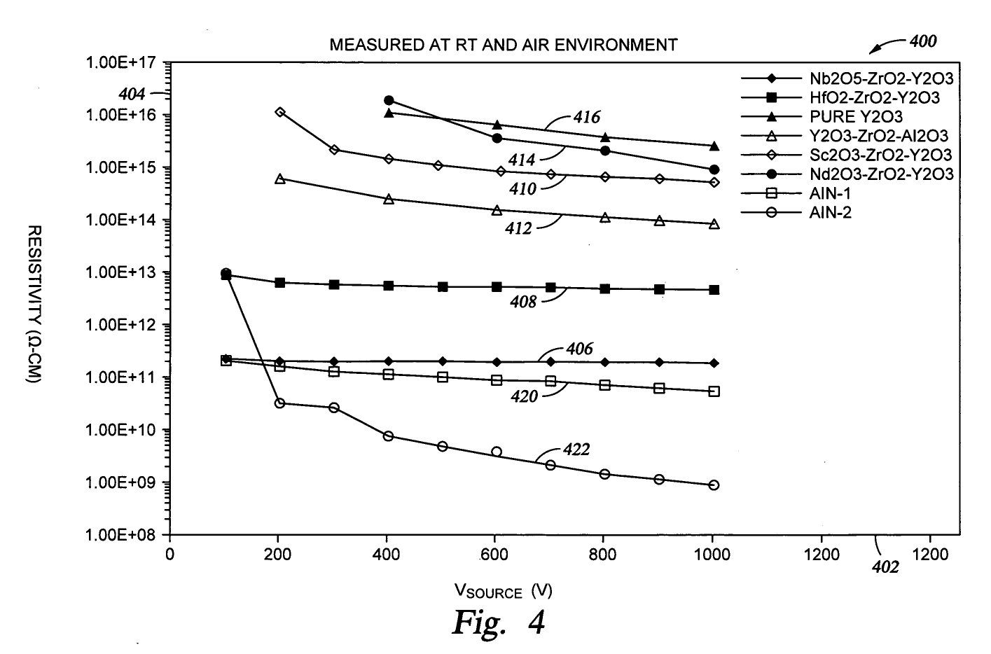

FIG. 4 is a graph 400 which illustrates the electrical resistivity, as a function of the voltage applied during the resistivity testing, for a number of sintered ceramic test specimens. The resistivity is shown on axis 404, with the voltage shown on axis 402. The test temperature is room temperature (about 27° C.). The purpose of this graph is to illustrate the differences in resistivity between the corrosion-resistant ceramic embodiments of the present invention which have been controlled to reduce resistivity and the currently used doped aluminum nitride ceramics. While the doped aluminum nitride ceramics have a somewhat lower resistivity, their corrosion rate is at least 2 times higher than that of the yttrium oxide-comprising ceramics which have been modified to reduce resistivity.

In particular, Curve 422 of FIG. 4 represents doped aluminum nitride ceramic of the kind currently used to fabricate an electrostatic chuck. Curve 420 represents another doped aluminum nitride ceramic which is used to fabricate an electrostatic chuck and other low resistivity components.

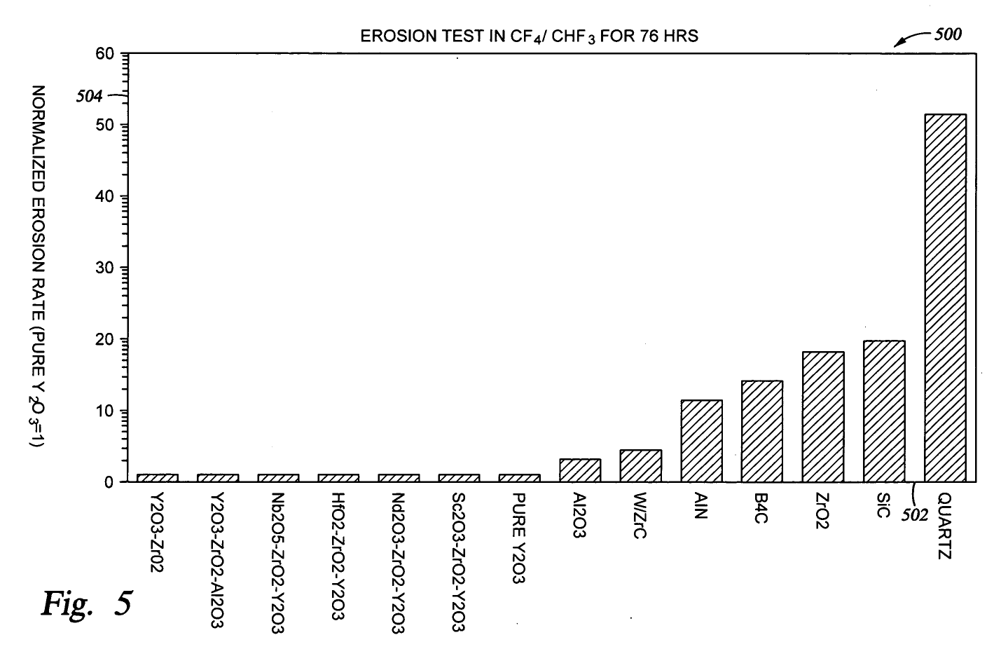

Curve 406 of FIG. 4 is representative of the Nb₂O₅-comprising sintered ceramic material which is described as Sample #4 in the Table. This yttrium-oxide comprising material which has been modified to reduce resistivity exhibits a resistivity which is very close to that of the doped aluminum nitride identified as AlN-1. Yet, the corrosion rate of the doped aluminum nitride is more than 10 times faster than the corrosion rate of the yttrium-oxide comprising material illustrated by curve 406, as is shown by the bar chart 500 in FIG. 5.

Curve 408 in FIG. 4 is representative of the HfO₂-comprising sintered ceramic material which is described as Sample #1 in the Table. This ceramic material exhibits a higher resistivity than the Nb₂O₅-comprising material, and at room temperature exhibits a resistivity which is outside of the recommended range for components where plasma arcing is more likely to occur. However, at 200° C., a temperature which is present during some semiconductor processing, the resistivity falls within an acceptable range, as illustrated by Curve 108 in FIG. 1.

Curve 410 of FIG. 4 is representative of the Sc₂O₃-comprising sintered ceramic material which is described as Sample 2 in the Table. Again, this material may be used in applications where the resistivity requirement is 10¹¹ Ω·cm, when the processing temperature is 200° C.

For comparative purposes (with respect to a controlled electrical resistivity ceramic containing a yttria-comprising solid solution), Curve 412 of FIG. 4 shows a ceramic type “A” material comprising Y₂O₃, ZrO₂, and Al₂O₃ which is illustrated in FIG. 2. One embodiment of such a type “A” material, which is shown in FIG. 1, contains about 60 molar % cubic yttria type structure with c-Y₂O₃ as a solvent and with Zr₂O₃ solute; about 2 molar % fluorite-type structure solid solution with ZrO₂ as a solvent and with Y₂O₃ solute; and, about 38 molar % YAM (Y₄Al₂O₉) compound. While the Type A HPM material exhibits acceptable corrosion-resistant properties and commendable mechanical properties, the electrical resistivity is considerably higher that the desired range maximum 10¹¹ Ω·cm. This is the case even at 200° C., as illustrated by Curve 112 in FIG. 1. This material is not included among the embodiments for the electrical resistivity modified corrosion resistant ceramics.

For comparative purposes, Curve 414 of FIG. 4 shows the Nd₂O₃— comprising sintered ceramic material which is described as Sample #3 in the Table. This material is failed to meet the requirements which are necessary to prevent arcing, and is considered to be a comparative example which is not part of the unique ceramic materials which make up the invention.

For comparative purposes, Curve 416 of FIG. 4 shows the electrical resistivity characteristics observed for a sintered ceramic of pure Y₂O₃. This material is also a comparative example, which is useful as a baseline, since a number of semiconductor apparatus components have been fabricated from pure Y₂O₃. A comparison of the resistivity of the pure Y₂O₃ shows the very significant improvement in terms of electrical resistivity which is achieved by the present invention.

### Example Eight

FIG. 5 illustrates a bar chart 500 which shows the average erosion rate, normalized to the erosion rate of Y₂O₃ for a variety of sintered ceramic materials exposed to a plasma. The plasma was generated from CF₄ and CHF₃ source gases. The plasma processing chamber was an Enabler for Trench Etch available from Applied Materials, Inc. The plasma source power was up to 2000 W, the process chamber pressure was 10-500 mTorr, and the substrate temperature was about 40° C., for a time period of 76 hours. The axis 502 shows a variety of materials which were tested for erosion resistance. The test specimen identified by a description Y2O3-10ZrO2, represent a sintered solid solution ceramic test specimen which was formed by sintering 100 parts by weight Y2O3 in combination with 10 parts by weight of ZrO2. The test specimens identified as containing Nb2O5-, or HfO2-, or Nd2O3-, or Sc2O3- represent the TABLE compositions which are recited as containing each of those materials. A comparison of the erosion rates as shown on axis 504 shows that the erosion rates of the resistivity modified, yttrium oxide-comprising sintered ceramic materials are essentially the same as the erosion rate for pure yttrium oxide. Further, the erosion rates of the resistivity modified, yttrium oxide-comprising sintered ceramics are substantially better than the erosion rate of Al2O3, AlN, ZrO₂, Quartz, W/ZrC, B4C and SiC, other ceramic materials which have been used to provide a halogen plasma corrosion-resistant materials for semiconductor processing chamber liners and on semiconductor processing apparatus interior components.

Based on the results obtained during the experimentation which provided the examples described above, and data from other reference sources, calculations have been made which provide estimates of the effect of UV radiation in plasma leakage current. UV radiation in a plasma environment (of the kind used in semiconductor processing) does not have an effect on leakage current of electrical resistivity-modified yttrium oxide-comprising sintered ceramic materials.

An investigation of the affect of 193 nm UV irradiation (which is employed in some semiconductor processing operations) on the leakage current in the Nb₂O₅-Type B sintered ceramic material and the HfO₂-Type B sintered ceramic material has indicated that the electrical performance of these materials should not be affected by such UV irradiation.

The ceramic-comprising articles which are useful as semiconductor processing apparatus which is in contact with a plasma include a lid, a liner, a nozzle, a gas distribution plate, a shower head, an electrostatic chuck component, a shadow frame, a substrate-holding frame, a processing kit, and a chamber liner, by way of example and not by way of limitation.

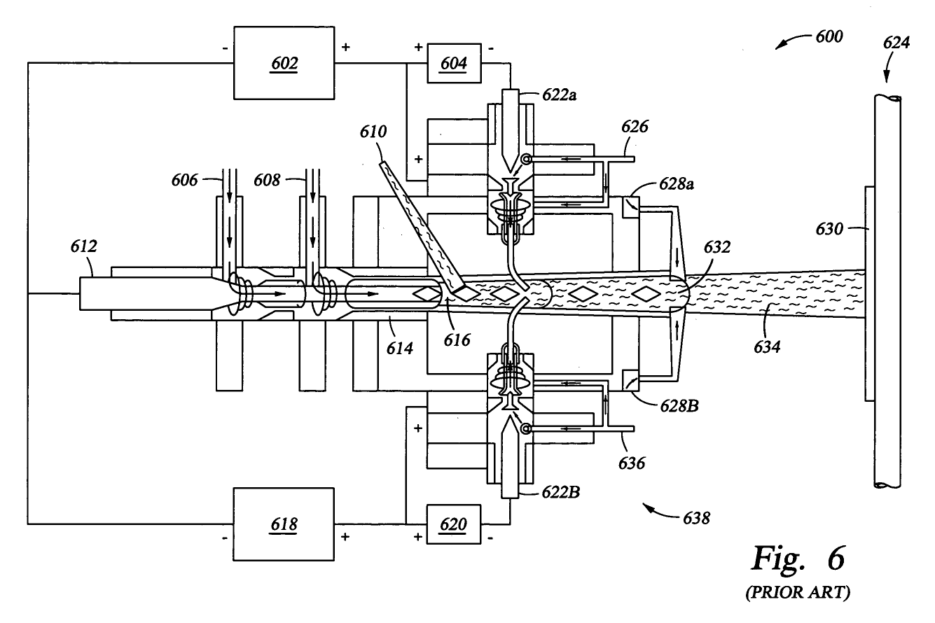

FIG. 6 is a cross-sectional schematic 600 of a type of plasma spraying system (a twin anode alpha torch 638) which is useful in applying the coatings of the present invention. The particular apparatus illustrated in FIG. 6 is an APS 7000 Series Aeroplasma Spraying System available from Aeroplasma K.K. (Tokyo, Japan). The apparatus 600 includes the following components: first DC main electrode 602; first auxiliary electrode 604; first argon source 606; first air source 608; spray material powder source 610; cathode torch 612; accelerator nozzle 614; plasma arc 616; second DC main electrode 618; second auxiliary electrode 620; dual anode torches 622A and 622B; second argon source 626; second air sources (plasma trimming) 628A and 628B; third argon source 636; plasma jet 632; molten powder source 634; and a base material source 624 which is to be sprayed.

Twin anode a torch 638 consists of two anode torches, so that each of the anode torches bears half of the thermal load. Using twin anode torch a 638, a high voltage can be obtained with relatively low current, so that the thermal load on each of the torches will be low. Each nozzle and electrode rod of the torches is water-cooled separately, and the arc starting point and ending point are protected by inert gas, so that stable operation at 200 hours or more is ensured, the service life of consumed parts is extended, and maintenance costs are reduced.

A high temperature stable arc is formed between the cathode torch 612 and the anode torch 622, and spray material can be fed directly into the arc. The spray material is completely melted by the high temperature arc column. The arc starting and ending points are protected by inert gas, so that air or oxygen can be used for the plasma gas introduced through the accelerator nozzle 614.

A plasma trimming function 628 is used for twin anode α. Plasma trimming trims the heat of the plasma jet that does not contribute to melting of the spray material, and reduces the thermal load on the substrate material and film to making spraying at short distances possible.

One skilled in the art will be able to adapt the method of the invention to a similar type of spray coating apparatus. The above described exemplary embodiments are not intended to limit the scope of the present invention, as one skilled in the art can, in view of the present disclosure, expand such embodiments to correspond with the subject matter of the invention claimed below.

We claim:

1. A method of spray-coating a surface of an article to provide erosion resistance to a halogen-containing plasma, wherein said coating is sprayed using a technique selected from the group consisting of flame spraying, thermal spraying and plasma spraying, and wherein said coating comprises at least one yttrium-containing solid solution.

2. A method in accordance with claim 1, wherein said coating major component is a solid solution which comprises a mixture of yttrium oxide and zirconium oxide.

3. A method in accordance with claim 2, wherein said coating is formed from precursor materials of yttrium oxide present over a range from about 40 molar % to less than 100 molar %, and zirconium oxide present over a range from more than 0 molar % to about 60 molar %.

4. A method in accordance with claim 1, wherein said coating is formed from precursor materials of yttrium oxide present over a range from about more than 80 molar % to less than 100 molar %, and cerium oxide present over a range from more than 0 molar % to about 20 molar %.

5. A method in accordance with claim 1, wherein said coating is formed from precursor materials of yttrium oxide present over a range from about more than 0 molar % to less than 100 molar %, and hafnium oxide is present over a range from more than 0 molar % to about 100 molar %.

6. A method in accordance with claim 1, wherein said coating is formed from precursor materials of yttrium oxide present over a range from about more than 48 molar % to less than 100 molar %, and niobium oxide is present over a range from more than 0 molar % to about 52 molar %.

7. A method in accordance with claim 2, wherein said coating is formed from precursor materials of yttrium oxide present over a range from about 50 molar % to about 75 molar %, zirconium oxide present over a range from about 10 molar % to about 30 molar %, and aluminum oxide present over a range from about 10 molar % to about 30 molar %.

8. A method in accordance with claim 1, wherein said coating is formed from precursor materials of yttrium oxide present over a range from about 40 molar % to less than about 100 molar %, zirconium oxide present over a range from more than 0 molar % to about 50 molar %, and scandium oxide is present over a range from more than about 0 molar % up to less than 100 molar %.

9. A method in accordance with claim 1, wherein said coating is formed from precursor materials of yttrium oxide present over a range from about 40 molar % to less than about 100 molar %, zirconium oxide present over a range from more than 0 molar % to about 50 molar %, and hafnium oxide is present over a range from more than about 0 molar % up to less than 100 molar %.

10. A method in accordance with claim 1, wherein said coating is formed from precursor materials of yttrium oxide present over a range from about 40 molar % to less than about 100 molar %, zirconium oxide present over a range from more than 0 molar % to about 45 molar %, and niobium oxide is present over a range from more than about 0 molar % up to less than 80 molar %.

11. A method in accordance with claim 10, wherein said coating contains three phases, which include a first phase solid solution comprising yttrium oxide, zirconium oxide and niobium oxide which makes up from about 5 molar % to about 30 molar % of the spray coated sintered ceramic coating; a second phase of Y₃NbO₇, which makes up from about 5 molar % to about 30 molar % of the spray coated sintered ceramic coating, and a third phase of Nb in elemental form, which makes up from about 1 molar % to about 10 molar % of the spray coated sintered ceramic coating.

12. A method in accordance with claim 1, wherein said spray-coating of said surface of said article is carried out while said surface of said article is at a temperature ranging from about 120° C. to a temperature which is less than a glass transition temperature of a material on said surface of said article.

13. A method in accordance with claim 1, wherein subsequent to said spray coating of said surface of said article, said surface is cleaned using a technique which comprises application of a dilute acid solution.

14. A method in accordance with claim 13, wherein said dilute acid solution contains fluorine.

15. A method in accordance with claim 1, wherein said surface of said article comprises a material selected from the group consisting of aluminum, aluminum alloy, stainless steel, alumina, aluminum nitride, quartz, and combinations thereof.

16. A of applying a coating a surface of an article to provide erosion resistance to a halogen-containing plasma, wherein said coating is sputter deposited from a target which comprises at least one yttrium-containing solid solution.

17. A method in accordance with claim 16, wherein a major component of said target is a solid solution which comprises a mixture of yttrium oxide and zirconium oxide.

18. A method in accordance with claim 17, wherein said target is formed from precursor materials of yttrium oxide present over a range from about 40 molar % to less than 100 molar %, and zirconium oxide present over a range from more than 0 molar % to about 60 molar %.

19. A method in accordance with claim 16, wherein said target is formed from precursor materials of yttrium oxide present over a range from about more than 80 molar % to less than 100 molar %, and cerium oxide present over a range from more than 0 molar % to about 20 molar %.

20. A method in accordance with claim 16, wherein said target is formed from precursor materials of yttrium oxide present over a range from about more than 0 molar % to less than 100 molar %, and hafnium oxide is present over a range from more than 0 molar % to about 100 molar %.

21. A method in accordance with claim 16, wherein said target is formed from precursor materials of yttrium oxide present over a range from about more than 48 molar % to less than 100 molar %, and niobium oxide is present over a range from more than 0 molar % to about 52 molar %.

22. A method in accordance with claim 17, wherein said target is formed from precursor materials of yttrium oxide present over a range from about 50 molar % to about 75 molar %, zirconium oxide present over a range from about 10 molar % to about 30 molar %, and aluminum oxide present over a range from about 10 molar % to about 30 molar %.

23. A method in accordance with claim 16, wherein said target is formed from precursor materials of yttrium oxide present over a range from about 40 molar % to less than about 100 molar %, zirconium oxide present over a range from more than 0 molar % to about 50 molar %, and scandium oxide is present over a range from more than about 0 molar % up to less than 100 molar %.

24. A method in accordance with claim 16, wherein said target is formed from precursor materials of yttrium oxide present over a range from about 40 molar % to less than about 100 molar %, zirconium oxide present over a range from more than 0 molar % to about 50 molar %, and hafnium oxide is present over a range from more than about 0 molar % up to less than 100 molar %.

25. A method in accordance with claim 16, wherein said target is formed from precursor materials of yttrium oxide present over a range from about 40 molar % to less than about 100 molar %, zirconium oxide present over a range from more than 0 molar % to about 45 molar %, and niobium oxide is present over a range from more than about 0 molar % up to less than 80 molar %.

26. A method in accordance with claim 25, wherein said target contains three phases, which include a first phase solid solution comprising yttrium oxide, zirconium oxide and niobium oxide which makes up from about 5 molar % to about 30 molar % of the spray coated sintered ceramic coating; a second phase of Y₃NbO₇, which makes up from about 5 molar % to about 30 molar % of the spray coated sintered ceramic coating, and a third phase of Nb in elemental form, which makes up from about 1 molar % to about 10 molar % of the spray coated sintered ceramic coating.

27. A method in accordance with claim 1, wherein said sputter deposition of said coating onto said surface of said article is carried out while said surface of said article is at a temperature ranging from about 120° C. to a temperature which is less than a glass transition temperature of a material on said surface of said article.

28. A method in accordance with claim 16, wherein subsequent to said sputter depositing of said coating on said surface of said article, said surface is cleaned using a technique which comprises application of a dilute acid solution.

29. A method in accordance with claim 28, wherein said dilute acid solution contains fluorine.

30. A method in accordance with claim 16, wherein said surface of said article comprises a material selected from the group consisting of aluminum, aluminum alloy, stainless steel, alumina, aluminum nitride, quartz, and combinations thereof.
